(19) United States
(12) Patent Application Publication
(10) Pub. No.: US 2015/0380486 A1
(43) Pub. Date: Dec. 31, 2015

(54) ELECTRONIC DEVICE

(71) Applicant: POSTECH ACADEMY-INDUSTRY FOUNDATION, Pohang (KR)

(72) Inventors: Taiuk RIM, Pohang (KR); Chang-Ki BAEK, Pohang (KR); Jae-Joon KIM, Pohang (KR)

(21) Appl. No.: 14/751,290

(22) Filed: Jun. 26, 2015

(30) Foreign Application Priority Data
Jun. 27, 2014 (KR) 10-2014-0080076

(51) Int. Cl. H01L 29/06; H01L 29/78

(52) U.S. Cl. CPC H01L 29/0673; H01L 29/78

(57) ABSTRACT

An electronic device includes: a substrate; a nanowire mesh formed on the substrate and including a plurality of crossing points cross-coupled with a plurality of unit nanowires; and a first electrode and a second electrode electrically connected to the nanowire mesh.

### CROSS-REFERENCE TO RELATED APPLICATION

This application claims priority to and the benefit of Korean Patent Application No. 10-2014-0080076 filed in the Korean Intellectual Property Office on Jun. 27, 2014, the entire contents of which are incorporated herein by reference.

### BACKGROUND OF THE INVENTION

(a) Field of the Invention

The present invention relates to an electronic device. More particularly, the present invention relates to an electronic device including a semiconductor with flexibility and elasticity.

(b) Description of the Related Art

A conventional electronic device is formed on a hard substrate and is not applicable to a curved surface of nature. An electronic device having flexibility may be worn on a human body and a shape of the electronic device is easily changed as a new technology beyond a current paradigm emerges.

However, if a thickness of a substrate is increased, a bending degree of the substrate is increased, so there is a need to increase a length of a device layer by several tens of percentage points or greater as compared with an original length. Hence, tensile fatigue exerts a negative influence upon the electrical characteristics and reliability of a device. Accordingly, a flexible electronic device essentially requires elasticity.

The above information disclosed in this Background section is only for enhancement of understanding of the background of the invention and therefore it may contain information that does not form the prior art that is already known in this country to a person of ordinary skill in the art.

### SUMMARY OF THE INVENTION

The present invention has been made in an effort to provide an electronic device including a semiconductor with elasticity and flexibility having advantages of providing the semiconductor which may be flexibly moved in a horizontal direction.

An exemplary embodiment of the present invention provides an electronic device including: a substrate; a nanowire mesh formed on the substrate and including a plurality of crossing points cross-coupled with a plurality of unit nanowires; and a first electrode and a second electrode electrically connected to the nanowire mesh.

The crossing point may be formed by cross-coupling the unit nanowire in one of X, Y, and T forms, and the crossing point is disposed at a predetermined interval.

The nanowire mesh may include one of an amorphous silicon semiconductor, a polycrystalline silicon semiconductor, a germanium semiconductor, a microcrystalline semiconductor, or a compound semiconductor.

The nanowire mesh may include a conductive impurity ion.

A width of the crossing point is greater than a width of the unit nanowire, and a width of the unit nanowire is 1 μm or less.

The substrate may include a flexible substrate.

The nanowire mesh may include a plurality of openings to surround the unit nanowire, and the opening may have one of a circular shape, an elliptical shape, or a polygonal shape.

Another embodiment of the present invention provides an electronic device including: a substrate; a nanowire mesh formed on the substrate and including a plurality of openings; and a first electrode and a second electrode electrically connected to the nanowire mesh.

The opening may be aligned in a predetermined shape.

The opening may have one of a circular shape, an elliptical shape, or a polygonal shape.

When the opening has a polygonal shape, a side of the opening may have a length of 1 μm or less, and the nanowire mesh may have a thickness of 1 μm or less.

The nanowire mesh disposed between adjacent openings may have a thickness of 1 μm or less.

When the opening has a polygonal shape, a width of the nanowire mesh disposed at a region in which vertexes of the adjacent openings meet each other may be greater than a width of a nanowire mesh disposed between sides of adjacent openings.

The nanowire mesh may include one of an amorphous silicon semiconductor, a polycrystalline silicon semiconductor, a germanium semiconductor, a microcrystalline semiconductor, or a compound semiconductor.

Yet another embodiment of the present invention provides an electronic device including: a substrate; a gate electrode formed on the substrate; a gate insulation layer formed on the gate electrode; a nanowire mesh formed on the gate insulation layer, and including a plurality of crossing points cross-coupled with a plurality of unit nanowires, a channel region, a source region, and a drain region; and a source electrode and a drain electrode electrically connected to the source region and the drain region of the nanowire mesh.

The gate electrode may include a first gate electrode having a same plane shape as a shape of the nanowire mesh overlapping with the gate electrode.

The electronic device further including a second gate electrode formed on the substrate and including a signal line overlapping with the first gate electrode and transferring a gate signal.

The gate insulation layer may surround the nanowire mesh.

The gate insulation layer may include a contact opening exposing the source region and the drain region, and the source electrode and the drain electrode may be connected to the source region and the drain region through the contact opening.

The crossing point may be formed by cross-coupling the unit nanowire in one of X, Y, and T forms, and the crossing point may be disposed at a predetermined interval.

Another embodiment of the present invention provides an electronic device including: a substrate; a gate electrode formed on the substrate; a gate insulation layer formed on the gate electrode; a nanowire mesh formed on the gate insulation layer, and including a plurality of openings, a channel region, a source region, and a drain region; and a source electrode and a drain electrode electrically connected to the source region and the drain region of the nanowire mesh.

The gate electrode may include a first gate electrode having a same plane shape as a shape of the nanowire mesh overlapping with the gate electrode.

The electronic device may further include a second gate electrode formed on the substrate and including a second gate electrode overlapping with the unit nanowire between the opening and the adjacent opening and transferring a gate signal, wherein the second gate electrode makes contact with the first gate electrode.

The gate insulation layer may surround the nanowire mesh.

The gate insulation layer may include a contact opening exposing the source region and the drain region, and the source electrode and the drain electrode may be connected to the source region and the drain region through the contact opening.

The nanowire mesh may have a thickness of 1 μm or less, and the nanowire mesh disposed between adjacent openings may have a thickness of 1 μm or less.

When the opening has a polygonal shape, a width of the nanowire mesh disposed at a region in which vertexes of the adjacent openings meet each other may be greater than a width of a nanowire mesh disposed between sides of the adjacent openings.

According to the present invention, if the semiconductor is formed, since the semiconductor is moved in a horizontal direction of a formed substrate, the semiconductor is transformed in concert so that a semiconductor device having elasticity may be provided.

According to the present invention, if the electronic device is formed to include a nanowire mesh, gate control performance is improved compared with an existing plate-type semiconductor, and the electronic device is advantageous in view of application to a high performance electronic device. Such characteristics may be used as a technology capable of increasing performance of a logic device and a thin film transistor device according to the related art.

Further, the electronic device has flexibility due to a thin thickness and an area of a nanowire mesh, and has optical transparency that is advantageous in combination with a light emitting device such as a display.

### BRIEF DESCRIPTION OF THE DRAWINGS

FIG. 1 is a plan view illustrating a nanowire mesh according to an exemplary embodiment of the present invention.

FIG. 2 is a cross-sectional view taken along line II-II of FIG. 1.

FIG. 3 is a plan view illustrating a nanowire mesh according to another exemplary embodiment of the present invention.

FIG. 4 is a scanning electron microscope (SEM) photographic view illustrating a nanowire mesh according to an exemplary embodiment of the present invention.

FIG. 5 is an SEM photographic view when the nanowire mesh of FIG. 4 extends.

FIG. 6 is a layout view illustrating a two terminal semiconductor device according to an exemplary embodiment of the present invention.

FIG. 7 is a cross-sectional view taken along line VII-VII of FIG. 6.

FIG. 8, FIG. 10, FIG. 12, and FIG. 14 are layout views sequentially illustrating a mesh crystalline semiconductor according to an exemplary embodiment of the present invention.

FIG. 9 is a cross-sectional view taken along line IX-IX of FIG. 8.

FIG. 11 is a cross-sectional view taken along line XI-XI of FIG. 10.

FIG. 13 is a cross-sectional view taken along line XIII-XIII of FIG. 12.

FIG. 15 is cross-sectional view taken along line XV-XV of FIG. 14.

FIG. 16 is a layout view illustrating a two terminal semiconductor device according to another exemplary embodiment of the present invention.

FIG. 17 is a cross-sectional view taken along line XVII-XVII of FIG. 16.

FIG. 18, FIG. 20, FIG. 23 are layout views sequentially illustrating a method of manufacturing a mesh crystalline semiconductor according to another exemplary embodiment of the present invention.

FIG. 19 is a cross-sectional view taken along line XIX-XIX of FIG. 18.

FIG. 21 is a cross-sectional view taken along line XXI-XXI of FIG. 20.

FIG. 22 is a cross-sectional view of a next step after FIG. 21.

FIG. 24 is a cross-sectional view taken along line XXIV-XXIV of FIG. 23.

FIG. 25 is a plan view illustrating a nanowire mesh transistor according to another exemplary embodiment of the present invention.

FIG. 26 is a cross-sectional view taken along line XXVI-XXVI of FIG. 25.

FIG. 27A is a graph illustrating subthreshold swing of a transistor according to an exemplary embodiment of the present invention and subthreshold swing of a transistor according to the related art.

FIG. 27B is a graph illustrating a threshold voltage Vth of a transistor according to an exemplary embodiment of the present invention and a threshold voltage Vth of a transistor according to the related art.

FIG. 27C is a graph illustrating hysteresis of a transistor according to an exemplary embodiment of the present invention and a transistor according to the related art.

FIG. 28 is a plan view illustrating a transistor in a middle step for describing a method of manufacturing a transistor according to another exemplary embodiment of the present invention.

FIG. 29 is cross-sectional view taken along line XXIX-XXIX of FIG. 28.

FIG. 30 is a cross-sectional view in a next step of FIG. 29.

FIG. 31 is a plan view in a next step of FIG. 30.

FIG. 32 is cross-sectional view taken along line XXXII-XXXII of FIG. 31.

FIG. 33 is a cross-sectional view in a next step of FIG. 32.

FIG. 34 is a plan view in a next step of FIG. 33.

FIG. 35 is a cross-sectional view taken along line XXXV-XXXV of FIG. 34.

### DETAILED DESCRIPTION OF THE EMBODIMENTS

Hereinafter, the present invention will be described more fully with reference to the accompanying drawings, in which exemplary embodiments of the invention are shown.

As those skilled in the art would realize, the described embodiments may be modified in various different ways, all without departing from the spirit or scope of the present invention.

In the drawings, the thickness of layers, films, panels, regions, etc., are exaggerated for clarity. Like reference numerals designate like elements throughout the specification.

It will be understood that when an element such as a layer, film, region, or substrate is referred to as being “on” another element, it can be directly on the other element or intervening elements may also be present. In contrast, when an element is referred to as being “directly on” another element, there are no intervening elements present.

Hereinafter, an electronic device according to the present invention will be described in detail with reference to the accompanying drawings.

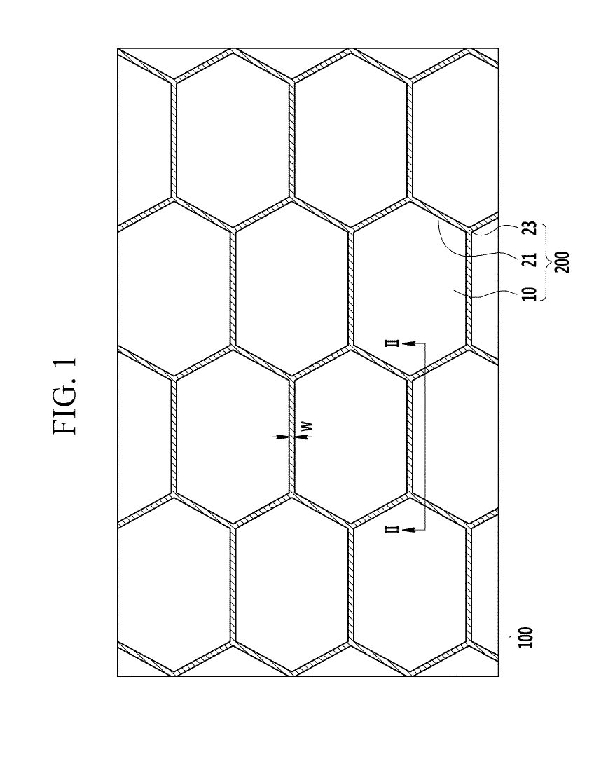

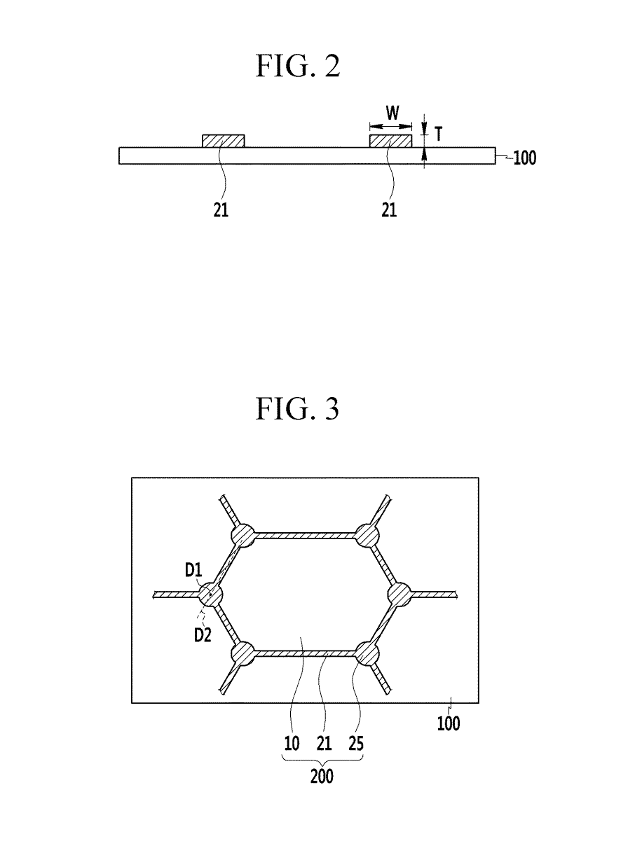

FIG. 1 is a plan view illustrating a nanowire mesh according to an exemplary embodiment of the present invention, FIG. 2 is a cross-sectional view taken along line II-II of FIG. 1, and FIG. 3 is a plan view illustrating a nanowire mesh according to another exemplary embodiment of the present invention.

As shown in FIG. 1 and FIG. 2, a semiconductor according to an exemplary embodiment of the present invention is a nanowire mesh 200 which is formed on a substrate 100 and includes a plurality of openings 10. The openings 10 may have a polygonal shape such as a triangle, a quadrangle, a pentagon, a hexagon, and an octagon, and may have the same size and shape.

The nanowire mesh may include one of an amorphous silicon semiconductor, a polycrystalline silicon semiconductor, a germanium semiconductor, a microcrystalline semiconductor, or a compound semiconductor.

The nanowire mesh 200 includes a unit nanowire 21 disposed between sides of adjacent openings 10, and a crossing point 23 disposed at a region in which vertexes of the adjacent openings 10 meet each other.

The crossing points 23 are formed by cross-coupling the unit nanowires 21 with each other, and are formed by cross-coupling the unit nanowires 21 in one of X, Y, and T shapes. Since the opening 10 surrounded by the unit nanowire 21 has a predetermined size and shape, the crossing points 23 are disposed at predetermined intervals.

A nanowire mesh 200 may have a thickness T of 1 μm or less, and the unit nanowire may have a width W1 of 1 μm or less.

In accordance with an exemplary embodiment of the present invention, if the nanowire mesh is formed, even if a substrate extends or is bent in a horizontal direction, since the semiconductors are moved together, a semiconductor device with improved elasticity may be provided.

That is, if the nanowire mesh is formed as shown in FIG. 2, when the substrate extends in the horizontal direction, a tensile force is applied to the nanowire mesh, and the substrate is moved in a tensile force direction together so that a shape the opening is changed, thereby increasing the elasticity of the semiconductor device.

The nanowire mesh of FIG. 3 is almost the same as the nanowire mesh of FIG. 1 such that only different parts will be described in detail.

The nanowire mesh 200 shown in FIG. 3 is formed on the substrate 100, and includes a plurality of openings 10 and a unit nanowire 21 disposed between sides of the openings 10.

The nanowire mesh 200 includes an extension crossing point 25 disposed at a region in which vertexes of the adjacent openings 10 meet each other.

The extension crossing point 25 is an extended form of the crossing point at which the unit nanowires 21 cross, and may extend toward an opening between the unit nanowires 21. The extension crossing points 25 may have the same size and shape. The extension crossing point 25 is symmetrical to a horizontal virtual center line D2 dividing a width of one unit nanowire forming the extension crossing point into two parts and passing through a center point D1 of a crossing point.

Accordingly, a width extension crossing point 25 is greater than a width of the semiconductor 21.

As an example, FIG. 3 illustrates that the extension crossing point 25 has a circular shape, but the extension crossing point 25 may have a polygonal shape (not shown) such as a triangle or a quadrangle.

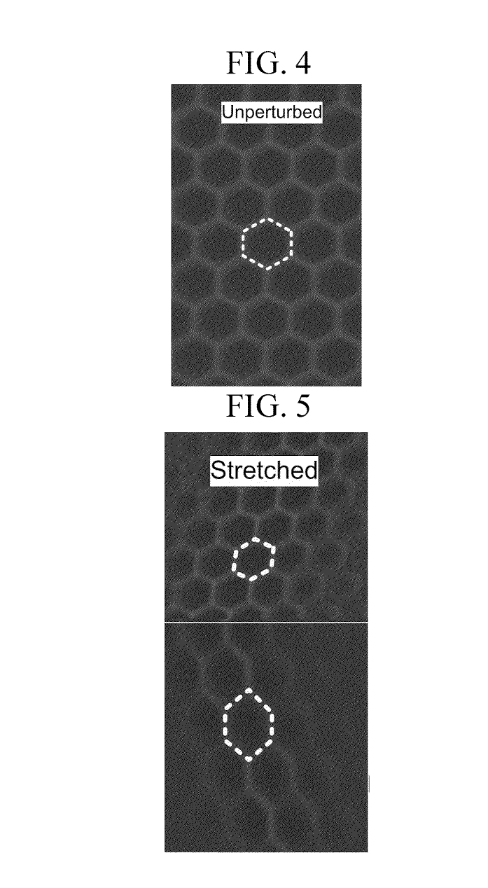

FIG. 4 is a scanning electron microscope (SEM) photographic view illustrating a nanowire mesh according to an exemplary embodiment of the present invention, and FIG. 5 is a SEM photographic view when the nanowire mesh of FIG. 4 extends.

The nanowire mesh of FIG. 4 is a nanowire mesh including a hexagonal opening. A width of the unit nanowire is 80 nm, a length of a side of an opening is 400 nm, and a thickness of a side of the opening is 100 nm.

As shown in FIG. 4, if the external force is not applied, the shape of the opening 10 may be normally maintained. Next, as shown in FIG. 5, when external force is applied, the shape of the opening 10 is changed, and the opening 10 is horizontally moved on a substrate and is transformed according to a shape of the substrate.

Further, FIG. 5 shows that an image of the nanowire mesh is blurred, when the substrate is stretched by external force. Since a focal length is fixed so that a microscope is in focus, the change of the shape of the nanowire mesh may be recognized by a blurred image of a microscope photograph.

In this way, when a nanowire mesh according to the present invention is formed, a shape of the substrate is three-dimensionally changed due to an external force applied to the substrate. In this case, the nanowire mesh may perform a horizontal direction motion and a vertical direction motion so that a three-dimensional motion is possible.

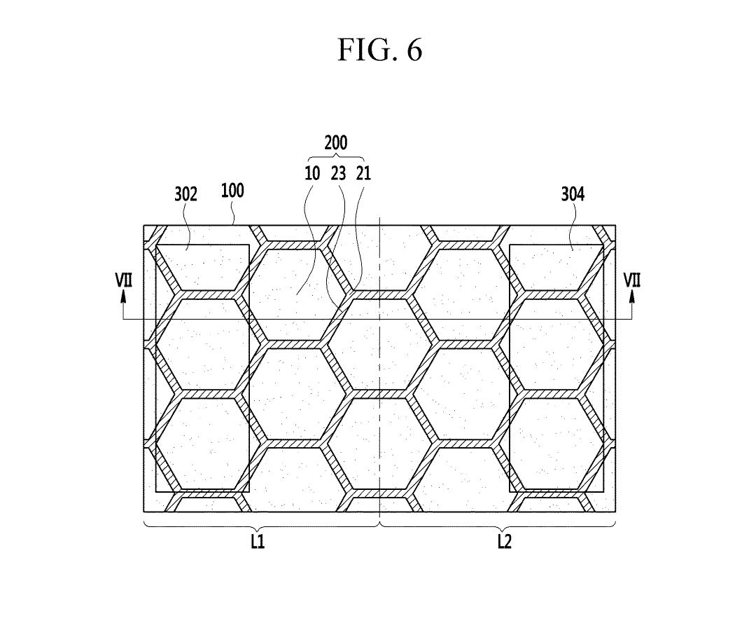

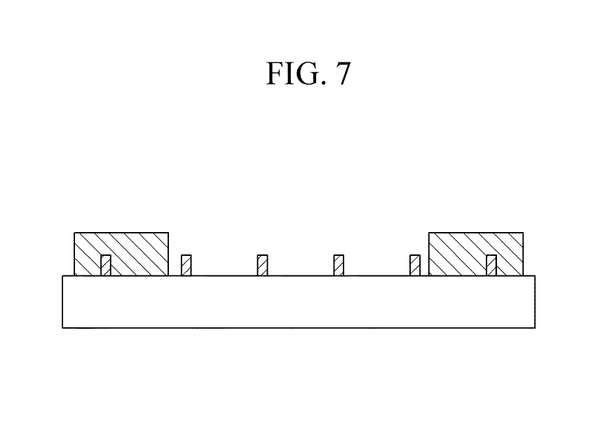

The above nanowire mesh may be used as a semiconductor of a two terminal semiconductor device such as an LED. This will be described with reference to FIG. 6 and FIG. 7.

FIG. 6 is a layout view illustrating a two terminal semiconductor device according to an exemplary embodiment of the present invention, and FIG. 7 is a cross-sectional view taken along line VII-VII of FIG. 6.

As shown in FIG. 6 and FIG. 7, the nanowire mesh is formed on the flexible substrate 100 having elasticity. The nanowire mesh 200 includes a hexagonal opening 10, and includes a crossing point 23 where unit nanowires 21 disposed between adjacent openings 10 cross.

The nanowire mesh 200 includes monocrystalline silicon, and includes a p-type doping region L1 and an n-type doping region L2 with p-type and n-type conductive impurities, respectively. The p-type doping region L1 and the n-type doping region L2 may form a pn junction.

Although the exemplary embodiment of FIG. 6 and FIG. 7 has described that a region of the nanowire mesh is divided into a p-type doping region and an n-type doping region, the pn junction may be formed by vertically stacking the nanowire mesh on which the p-type doping region is formed and the nanowire mesh on which the n-type doping region is formed.

A first electrode 302 and a second electrode 304 are formed on respective ends of the nanowire mesh 200. The first electrode 302 and the second electrode 304 are electrically connected to the p-type doping region L1 and the n-type doping region L2, respectively.

Hereinafter, a method of manufacturing a two terminal semiconductor device including a nanowire mesh according to an exemplary embodiment of the present invention will be described.

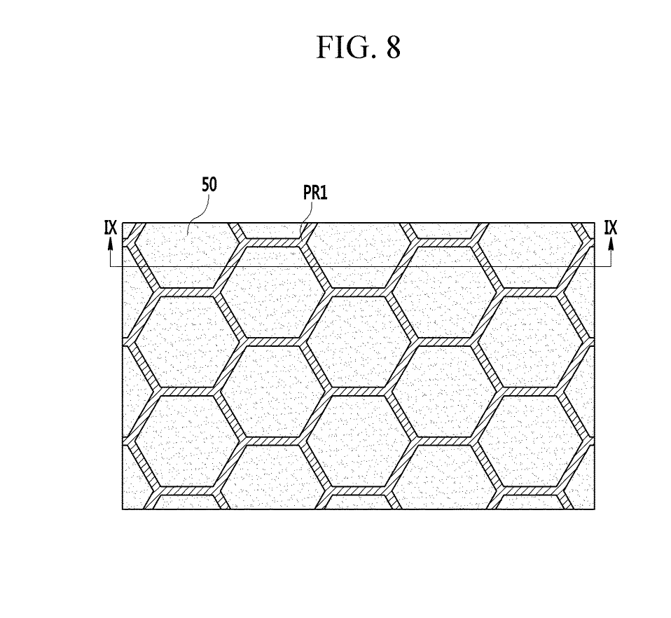

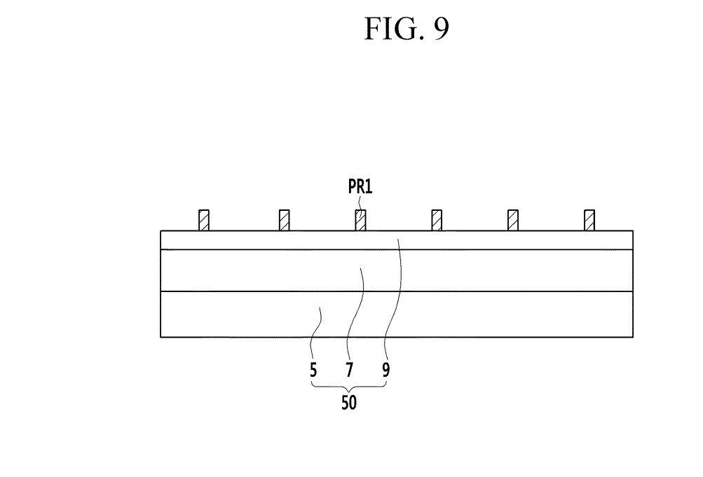

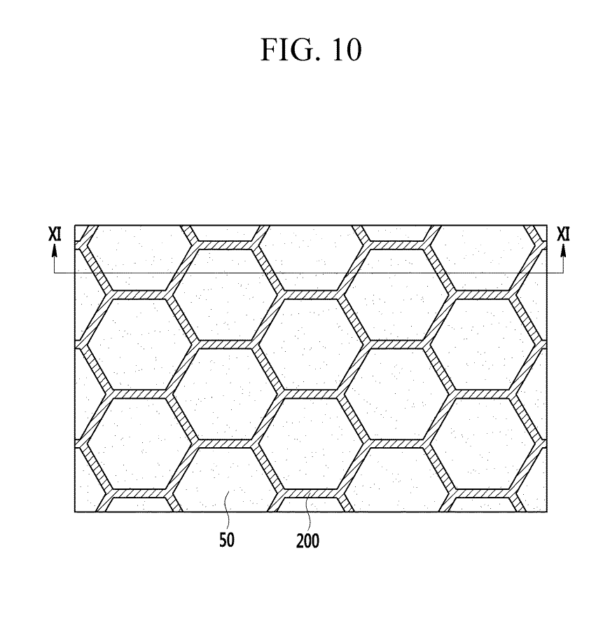

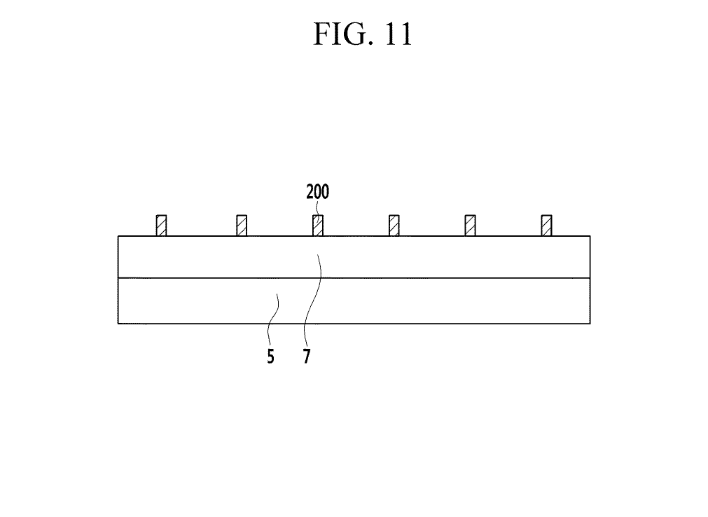

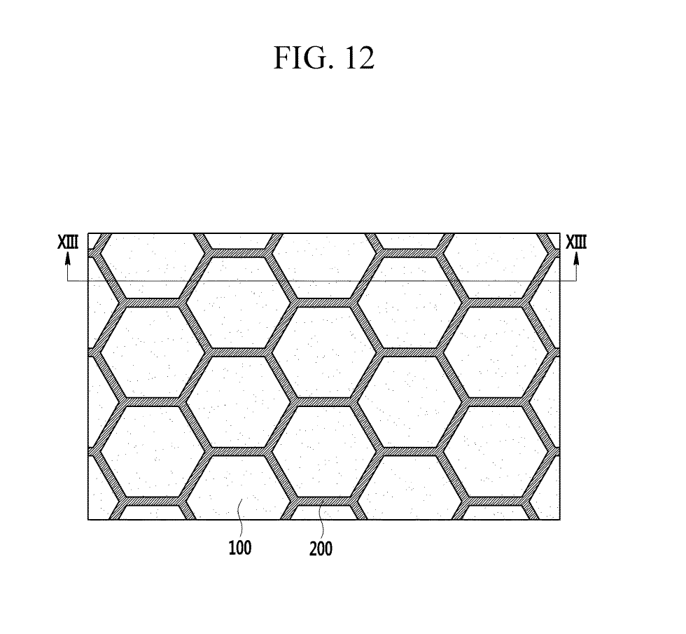

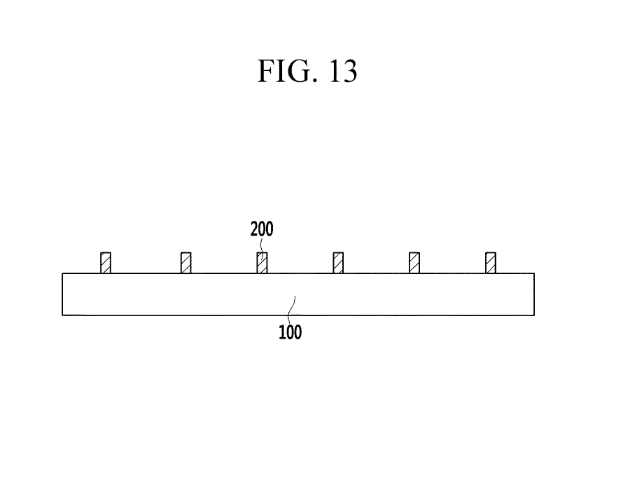

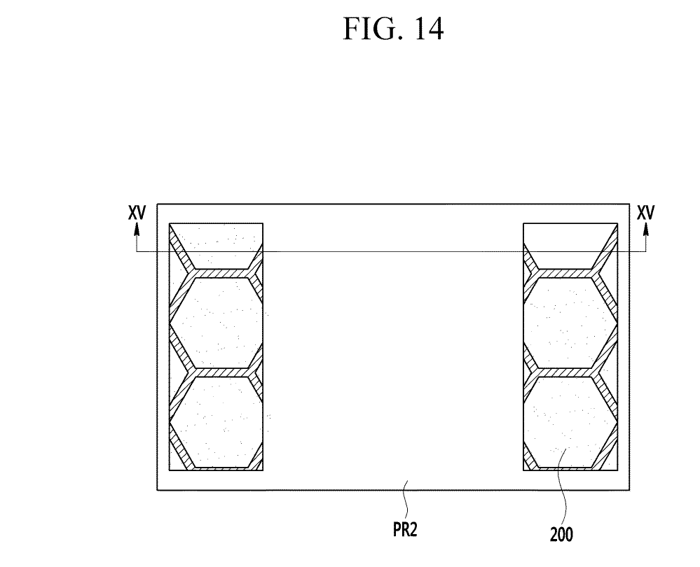

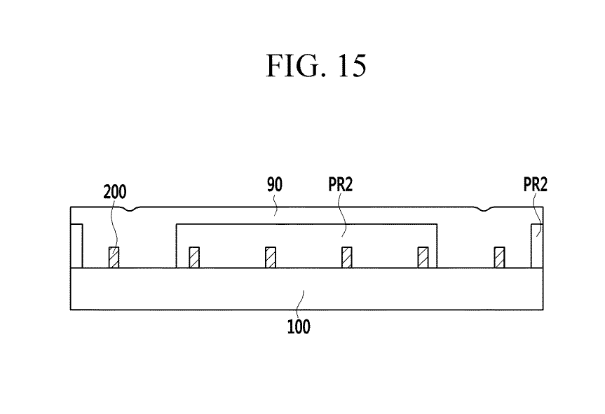

FIG. 8, FIG. 10, FIG. 12, and FIG. 14 are layout views sequentially illustrating a mesh crystalline semiconductor according to an exemplary embodiment of the present invention. FIG. 9 is a cross-sectional view taken along line IX-IX of FIG. 8, FIG. 11 is a cross-sectional view taken along line XI-XI of FIG. 10, FIG. 13 is a cross-sectional view taken along line XIII-XIII of FIG. 12, and FIG. 15 is a cross-sectional view taken along line XV-XV of FIG. 14.

As shown in FIG. 8 and FIG. 9, a substrate 50 is prepared. The substrate 50 is a silicon-on-insulator (SOI) substrate. The substrate 50 includes a support substrate 5 made of monocrystalline silicon, a silicon oxide layer 7, and a monocrystalline silicon layer 9 which are stacked. Moreover, a polycrystalline silicon or an amorphous silicon layer may be formed on the silicon oxide layer 7, and may be selectively formed according to a semiconductor device to be formed.

After a photosensitive layer is coated on the substrate 50, the resulting object is exposed and developed so that a first photosensitive layer pattern PR1 is formed.

Next, as shown in FIG. 10 and FIG. 11, a nanowire mesh 200 is formed by etching the monocrystalline silicon layer by using the first photosensitive layer pattern PR1 as a mask.

Next, as shown in FIG. 12 and FIG. 13, after removing the first photosensitive layer pattern PR1, the nanowire mesh 200 is separated from the support substrate 5 by etching the silicon oxide layer 7 disposed at a lower portion of the nanowire mesh 200.

The silicon oxide layer 7 is removed by wet etching such as anisotropic etching. Accordingly, the silicon oxide layer 7 is removed with the same etch rate.

Next, the separated nanowire mesh 200 is transferred onto the flexible substrate 100. The transfer is performed in a wet etch solution in which the anisotropic etching is performed, or the separated nanowire mesh 200 is transferred on the flexible substrate 100 after floating the nanowire mesh in a separate floating solution.

After that, a p-type doping region and an n-type doping region are formed by doping a p-type conductive impurity and an n-type conductive impurity into the nanowire mesh 200.

The p-type doping region and the n-type doping region are formed by doping the impurity into the nanowire mesh 200 before etching the silicon oxide layer.

The p-type doping region and the n-type doping region may each be formed by using a mask.

Next, as shown in FIG. 14 and FIG. 15, a second photosensitive layer pattern PR2 having a contact hole 68 exposing the nanowire mesh 200 is formed on the nanowire mesh 200.

A metal layer 90 is then formed on the second photosensitive layer pattern PR2 having a contact hole 68.

As shown in FIG. 6 and FIG. 7, the second photosensitive layer pattern PR2 is removed by a lift-off process to only maintain the metal layer in the contact hole 68 so that the first and second electrodes 302 and 304 electrically connected to the nanowire mesh 200 are manufactured.

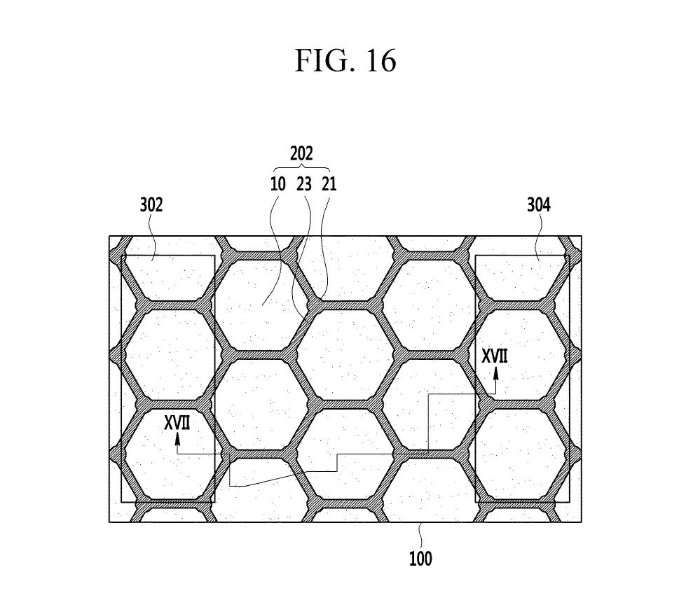

Hereinafter, a method of manufacturing the nanowire mesh according to another exemplary embodiment of the present invention will be described with reference to FIG. 16 to FIG. 19.

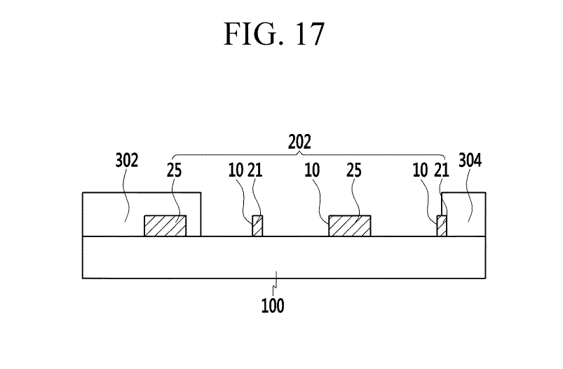

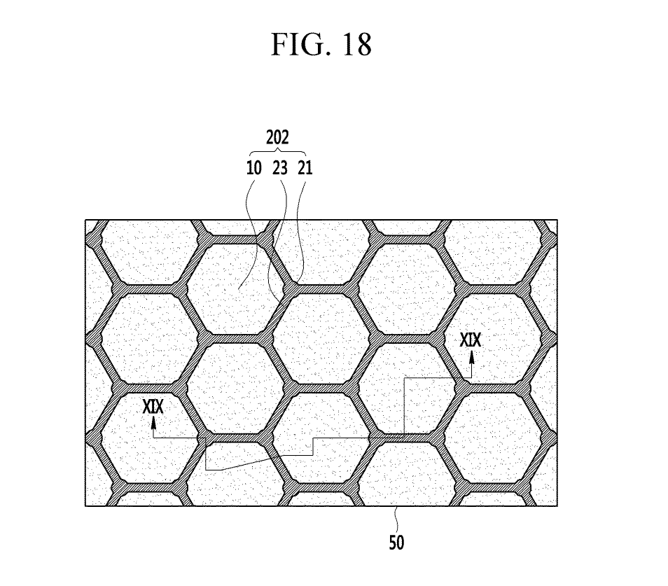

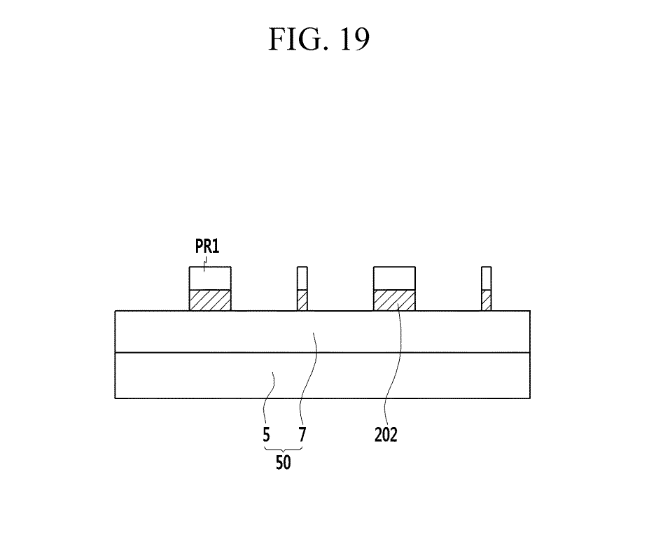

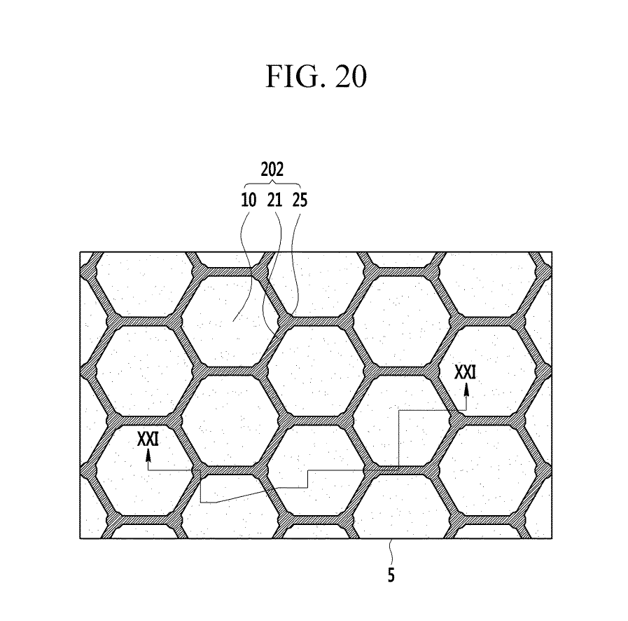

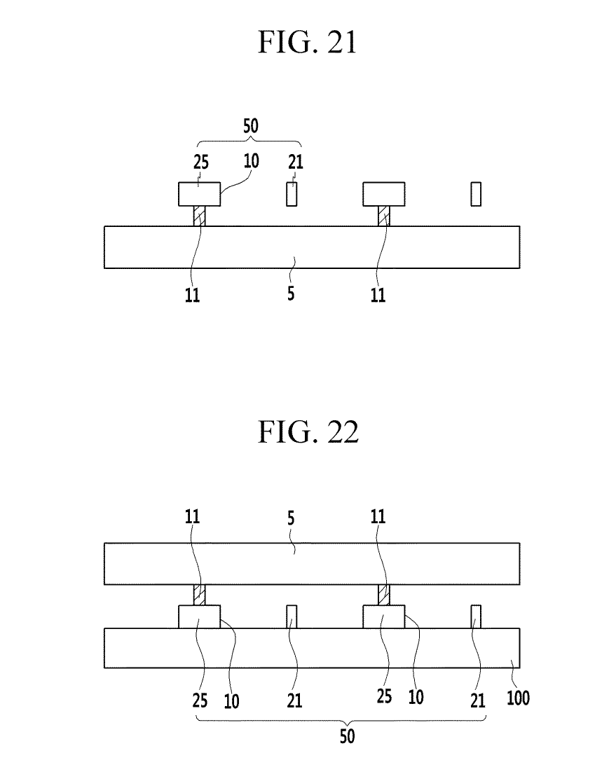

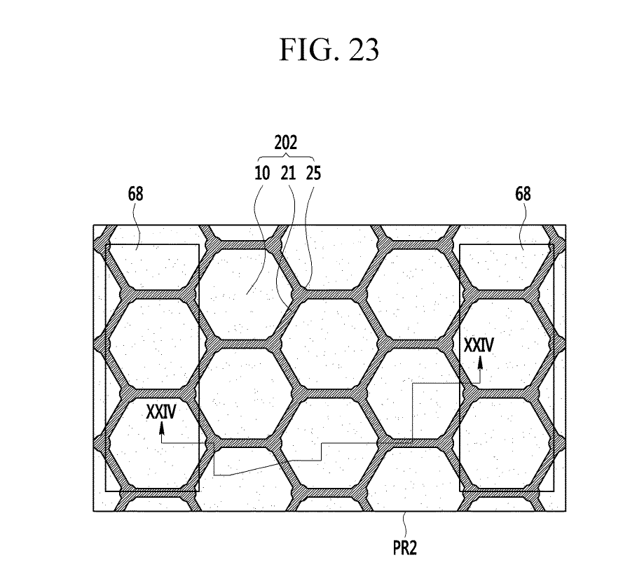

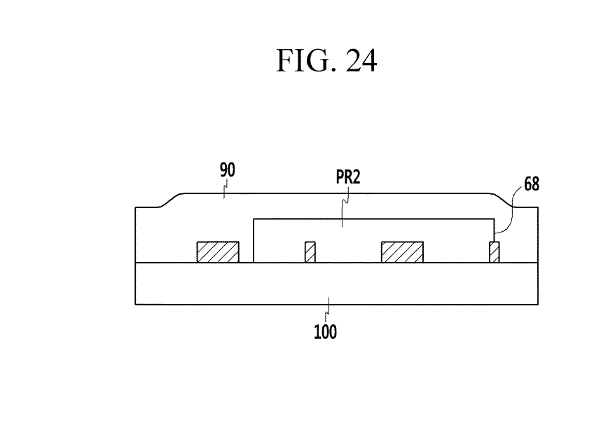

FIG. 16 is a layout view illustrating a two terminal semiconductor device according to another exemplary embodiment of the present invention. FIG. 17 is a cross-sectional view taken along line XVII-XVII of FIG. 16. FIG. 18, FIG. 20, and FIG. 23 are layout views sequentially illustrating a method of manufacturing a mesh crystalline semiconductor according to another exemplary embodiment of the present invention, FIG. 19 is a cross-sectional view taken along line XIX-XIX of FIG. 18, FIG. 21 is a cross-sectional view taken along line XXI-XXI of FIG. 20, FIG. 22 is a cross-sectional view in a next step, and FIG. 24 is a cross-sectional view taken along line XXIV-XXIV of FIG. 23.

First, as shown in FIG. 18 and FIG. 19, an SOI substrate is prepared, a first photosensitive layer pattern PR1 is formed, and a monocrystalline silicon layer is etched so that the nanowire mesh 202 is formed. In this case, the nanowire mesh 202 includes a unit nanowire 21 and an extension crossing point 25.

After that, as shown in FIG. 20 and FIG. 21, the unit nanowire 21 is separated from a silicon oxide layer disposed at a lower portion of the nanowire mesh 202 by etching the silicon oxide layer.

The silicon oxide layer 7 is removed by wet etching such as anisotropic etching so that the silicon oxide layer 7 is etched with the same etch rate.

In this case, since the width of the extension crossing point 25 is greater than a width of the unit nanowire 21, after the silicon oxide layer under the unit nanowire 21 is all removed, the silicon oxide layer under the extension crossing point 25 is not all removed but is maintained so that a connection pillar 11 is formed.

As shown in FIG. 12 and FIG. 13, when the entire silicon oxide layer is removed so that the nanowire mesh floats, a shape of the nanowire mesh may be distorted. However, as shown in FIG. 20 and FIG. 21, when the extension crossing point 25 is included, the entire silicon oxide layer is not removed under the extension crossing point 25 so that the connection pillar 11 is formed. Accordingly, the nanowire mesh 202 does not float but is fixed to the support substrate 5 so that a shape of the semiconductor 202 may be maintained.

Next, as shown in FIG. 22, the nanowire mesh 202 is transferred on the flexible substrate 100. In this case, the transfer is performed in a wet etching solution in which the anisotropic etching is performed or the nanowire mesh 200 is transferred in a separate floating solution. Further, since the nanowire mesh 202 is supported at the support substrate 5, it may be directly transferred onto the flexible substrate 100 without the etching solution or a separate floating solution.

Next, as shown in FIG. 23 and FIG. 24, the support substrate 5 connected by the connection pillar 11 is removed. The support substrate 5 may be removed by applying a physical force thereto.

A p-type doping region and a n-type doping region are then formed by doping p-type conductive impurities and n-type conductive impurities to the nanowire mesh 202.

The p-type doping region and the n-type doping region may be formed by doping to the nanowire mesh 202 before etching the silicon oxide layer.

The p-type doping region and the n-type doping region may each be formed by using a mask.

Next, a photosensitive layer pattern having a contact hole 68 exposing the nanowire mesh 202 is formed on the nanowire mesh 202.

A metal layer 90 is then formed on a photosensitive layer pattern including the contact hole 68.

Subsequently, as shown in FIG. 16 and FIG. 17, the photosensitive layer pattern is removed by a lift-off process to maintain the metal layer only in the contact hole 68 so that a first electrode 302 and a second electrode 304 electrically connected to the nanowire mesh 202 are manufactured.

The above nanowire mesh may be used as a semiconductor of a driving transistor or a switching transistor of a display device such as a liquid crystal display device or an organic light emitting display device.

Hereinafter, a transistor including a nanowire mesh and a method of manufacturing the same will be described in detail.

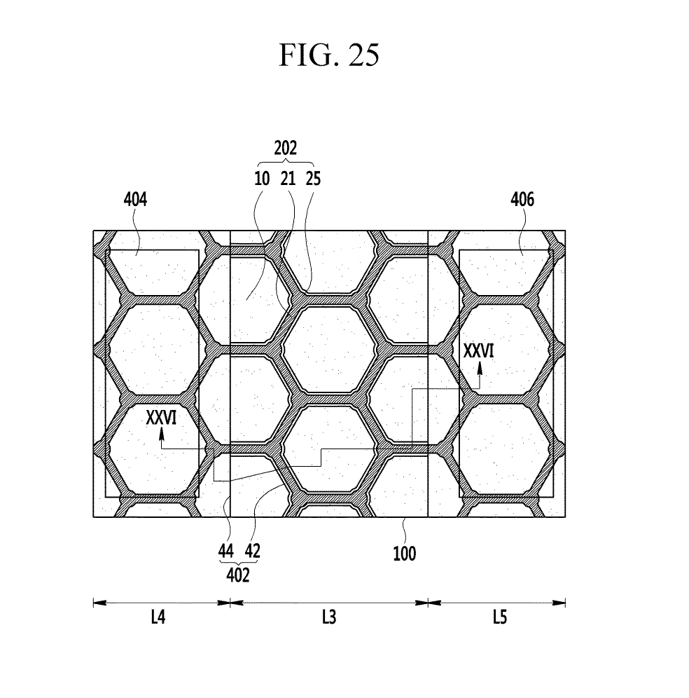

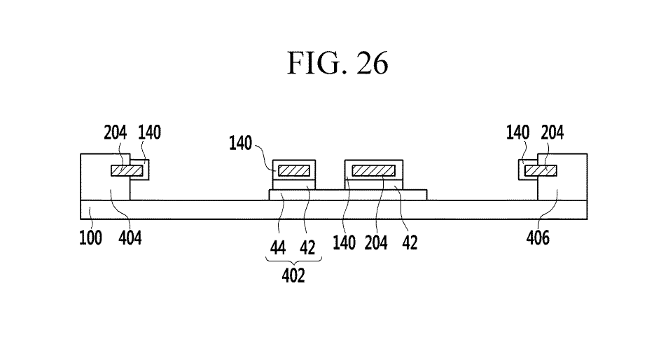

FIG. 25 is a plan view illustrating a nanowire mesh transistor according to another exemplary embodiment of the present invention, and FIG. 26 is a cross-sectional view taken along line XXVI-XXVI of FIG. 25.

As shown in FIG. 25 and FIG. 26, a transistor according to an exemplary embodiment of the present invention includes a substrate 100, a gate electrode 402 formed on the substrate 100, a gate insulation layer 140 formed on the gate electrode 402, a nanowire mesh 200 overlapping with the gate insulation layer 140, and a source electrode 404 and a drain electrode 406 connected to the nanowire mesh 204.

The substrate 100 may include a flexible substrate having elasticity. For example, the substrate 100 may include polydimethylsiloxane (PDMS).

The gate electrode 402 includes a first gate electrode 42 and a second gate electrode 44. The first gate electrode 42 may have the same plane shape as that of the nanowire mesh. The second gate electrode 44 is connected to a signal line (not shown) to transfer a gate signal.

Further, the gate electrode 402 is patterned so that a signal line is connected to an end of the first gate electrode 42 so that only a first gate electrode of a single layer may be achieved or only a second gate electrode may be achieved.

The gate electrode 402 may include a metal layer such as Ti, W, Au, Ag, and Cu, or may include a flexible conductor with a conductive nanowire or conductive nanoparticles.

The first gate electrode 42 and the second gate electrode 44 may be formed of the same or different materials, that is, the first gate electrode 42 is formed of a nanowire and the second gate electrode 44 is formed of a metal layer.

The gate insulation layer 140 may include at least one of a silicon oxide, a metal oxide, and an organic material.

As shown FIG. 1 and in FIG. 2, the nanowire mesh 204 may include an opening 10 surrounded by the unit nanowire 21, and may further include an extension crossing point 25 as shown in FIG. 3.

The same as in FIG. 1 to FIG. 3, a nanowire mesh 204 may include one of an amorphous silicon semiconductor, a polycrystalline silicon semiconductor, a germanium semiconductor a microcrystalline semiconductor, or a compound semiconductor, which may be selected according to characteristics of a device to be formed.

The nanowire mesh 204 includes a channel region L3 being an intrinsic region, and a source region L4 and a drain region L5 which are disposed at respective sides of the channel region L3 and are doped with a conductive impurity at a high concentration. The channel region L3 overlaps with the gate electrode 402, and the source region L4 and a drain region L5 overlap with a source electrode 404 and a drain electrode 406, respectively.

The source electrode 404 and the drain electrode 406 may be formed of the same material as that of the gate electrode 402. Further, the source electrode 404 and the drain electrode 406 may be formed of a plurality of layers including a low resistance conductive material.

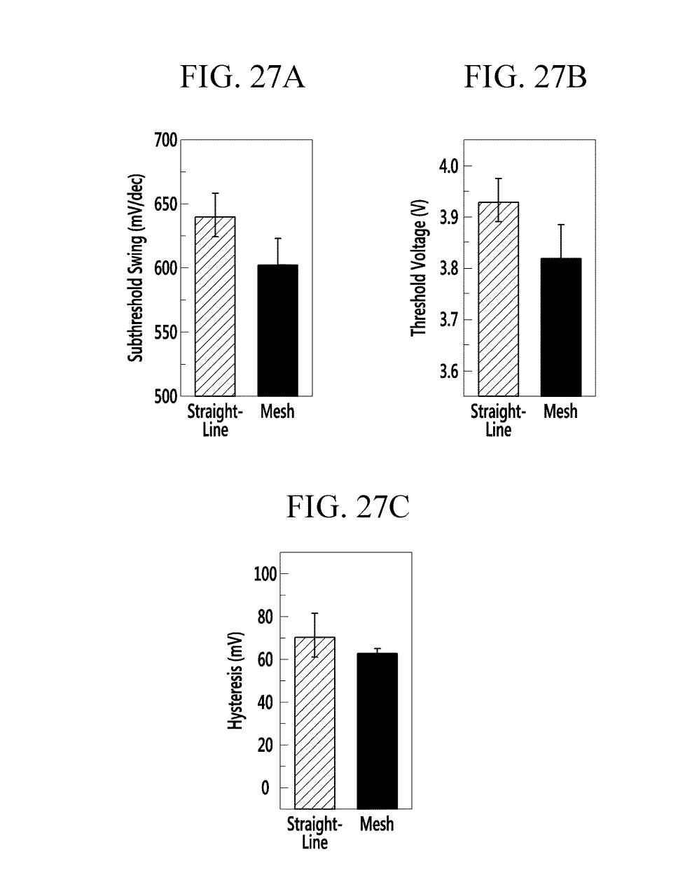

FIG. 27A is a graph illustrating subthreshold swing of a transistor according to an exemplary embodiment of the present invention and subthreshold swing of a transistor according to the related art, FIG. 27B is a graph illustrating a threshold voltage Vth of a transistor according to an exemplary embodiment of the present invention and a threshold voltage Vth of a transistor according to the related art, and FIG. 27C is a graph illustrating hysteresis of a transistor according to an exemplary embodiment of the present invention and a transistor according to the related art.

In FIG. 27A to FIG. 27C, the transistor according to an exemplary embodiment of the present invention includes a nanowire mesh of FIG. 1, and the transistor according to the related art includes a straight-line nanowire semiconductor.

Referring to FIG. 27A to FIG. 27C, the subthreshold swing and Vth of the transistor according to the present invention are lower than the subthreshold swing and Vth according to the related art.

Since the hysteresis according to the present invention is lower than that of the related art, influence of a trap generated from the straight-line nanowire according to the related art does not occur so that a stable transistor may be implemented.

In this way, as compared with the related art, channel control capacity and stability due to a gate electrode of a transistor including the nanowire mesh according to the present invention are improved so that the transistor may be used in a display device necessary for rapid drive and control.

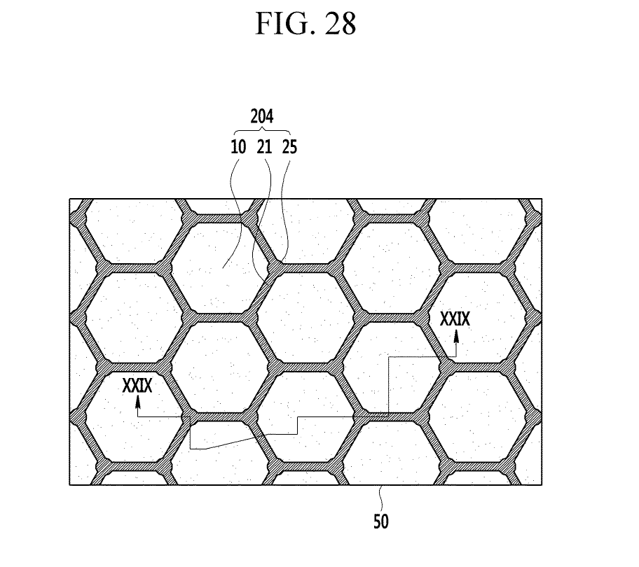

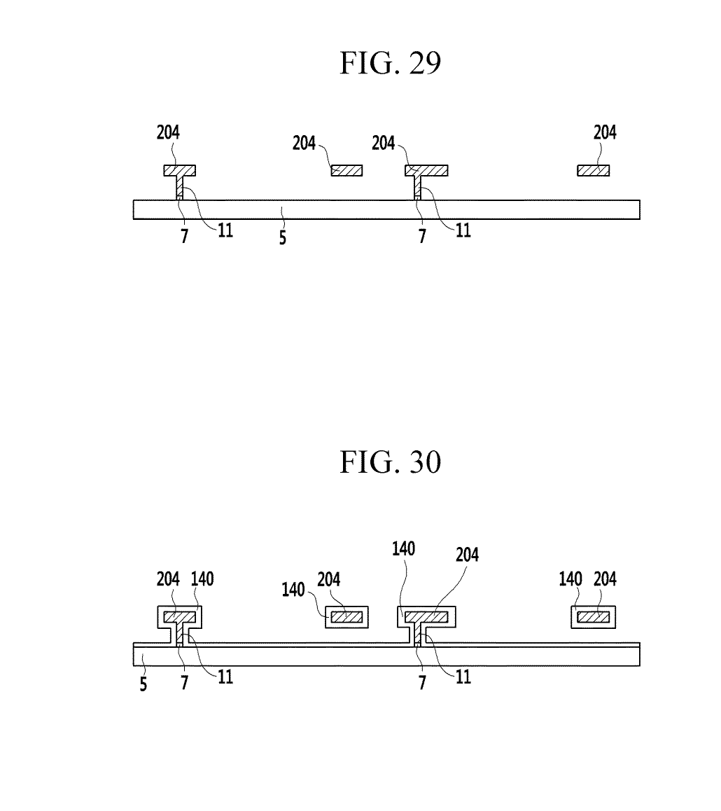

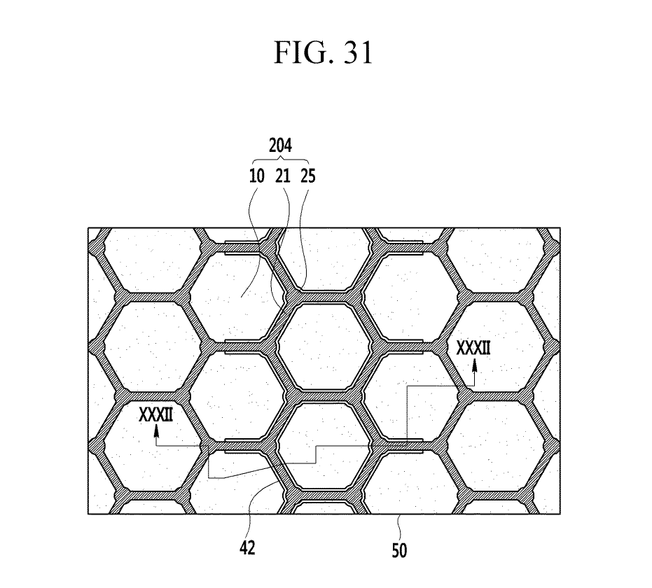

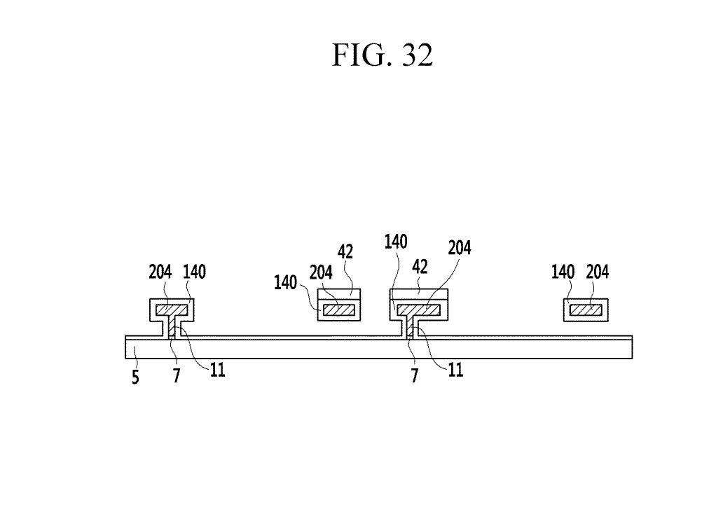

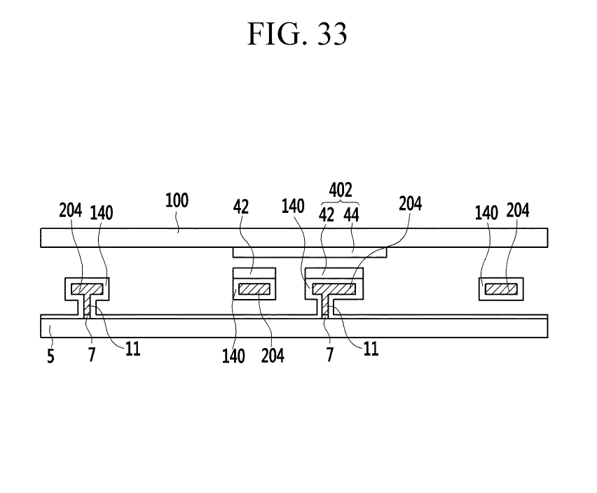

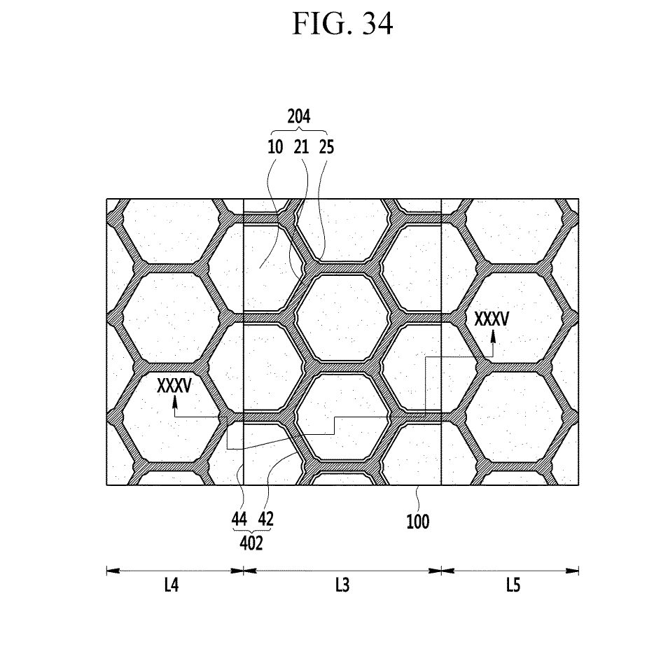

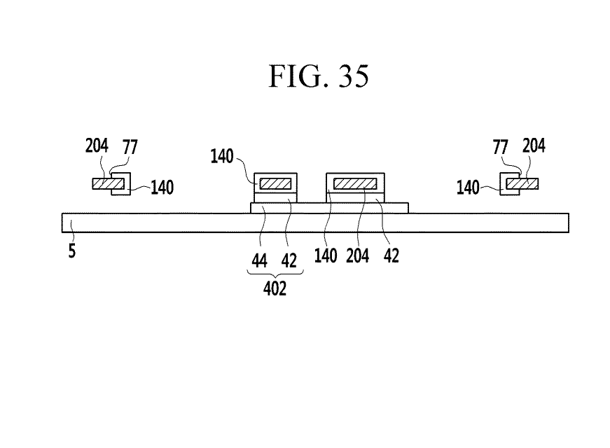

Hereinafter, a method of manufacturing a transistor according to another exemplary embodiment of the present invention of FIGS. 25 and 26 will be described in detail with reference to FIG. 28 to FIG. 35. FIG. 28 is a plan view illustrating a transistor in a middle step for describing a method of manufacturing a transistor according to another exemplary embodiment of the present invention, FIG. 29 is cross-sectional view taken along line XXIX-XXIX of FIG. 28, FIG. 30 is a cross-sectional view in a next step of FIG. 29, FIG. 31 is a plan view in a next step of FIG. 30, FIG. 32 is cross-sectional view taken along line XXXII-XXXII of FIG. 31, FIG. 33 is a cross-sectional view in a next step of FIG. 32, FIG. 34 is a plan view in a next step of FIG. 33, and FIG. 35 is a cross-sectional view taken along line XXXV-XXXV of FIG. 34.

First, as shown in FIG. 18 and FIG. 19, the nanowire mesh 202 is formed on the SOI substrate 50 on which the support substrate 5, the silicon oxide layer 7, and a monocrystalline silicon layer 9 are formed. In this case, the nanowire mesh 202 includes a unit nanowire 21 and an extension crossing point 25.

Next, as shown in FIG. 28 and FIG. 29, a unit nanowire 21 is separated from the silicon oxide layer 7 by etching the silicon oxide layer 7 disposed at a lower portion of the nanowire mesh 204.

The silicon oxide layer 7 is removed by wet etching such as anisotropic etching so that the silicon oxide layer 7 is etched with the same etch rate and a connection pillar 11 is formed under the extension crossing point 25.

Next, a channel region being an intrinsic region and a source region and a drain region being high concentration regions are formed by doping conductive impurities into a part of the nanowire mesh 204 using mask.

In this case, the conductive impurities may include a p-type or n-type conductive impurity, and may be formed by forming the nanowire mesh before etching the silicon oxide layer to dope the nanowire mesh.

Further, a junctionless transistor may be manufacture by uniformly doping to the entire silicon layer with mask.

Next, as shown in FIG. 30, a gate insulation layer 140 is formed on the nanowire mesh 204. The gate insulation layer 140 is formed by thermal oxidation so that the gate insulation layer 140 is formed to surround a surface of the nanowire mesh 204.

Further, the gate insulation layer 140 may be formed by atomic layer deposition or chemical vapor deposition (CVD), and may have a single layered structure or a multi-layered structure including at least one of a silicon oxide, a silicon nitride, a metal oxide, or an organic material insulation layer.

Next, as shown in FIG. 31 and FIG. 32, a first gate electrode 42 is formed on the gate insulation layer 140.

The first gate electrode 42 may be formed by forming and patterning the metal layer, and may be formed by an inkjet process using a conductive solution, and a solution including a nanowire and nanoparticles.

Since the first gate electrode 42 is formed on the nanowire mesh 204, the first gate electrode 42 may have the same plane shape as the nanowire mesh 204.

Next, as shown in FIG. 33 and FIG. 34, a flexible substrate 100 on which the second gate electrode 44 is formed is prepared.

The second gate electrode 44 may be formed by forming and patterning the metal layer, or by an inkjet print method using a conductive solution including nanoparticles or a nanowire.

After the second gate electrode 44 of the flexible substrate 100 is aligned to make contact with the first gate electrode 42, the second gate electrode 44 is pressed so that the nanowire mesh 204 is transferred onto the flexible substrate 100.

In the nanowire mesh in which the connection pillar 11 is not formed, the flexible substrate may be transferred in a wet etching solution in which the anisotropic etching is performed, or may be transferred in a separate floating solution.

After that, as shown in FIG. 35, the support substrate is separated from the nanowire mesh 204 by applying a physical force to the connection pillar 11 to cut the connection pillar.

Next, a contact opening 77 is formed by removing a part of the gate insulation layer 140 to expose a source region and a drain region of the nanowire mesh 204.

Next, as shown in FIG. 25 and FIG. 26, after forming and patterning the metal layer, a source electrode 404 and a drain electrode 406 making contact with the source region and a drain region of the nanowire mesh 204 through the contact opening 77. The source electrode 404 may be connected to a data line in order to receive a data signal of the display device, and the drain electrode may be connected to a pixel electrode of the display device.

While this invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

<Description of symbols>

| | |
|---|---|
| 5: support substrate | 7: silicon layer |

| | |
|---|---|
| 9: monocrystalline silicon layer | 10, 77: opening |

| | |
|---|---|
| 11: connection pillar | 21: unit nanowire |
| 23: crossing point | 25: extension crossing point |
| 42: first gate electrode | 44: second gate electrode |
| 50, 100: substrate | 90: metal layer |
| 140: gate insulation layer | 200, 202, 204: nanowire mesh |
| 302: first electrode | 304: second electrode |
| 402: gate electrode | 404: source electrode |

406: drain electrode

What is claimed is:

1. An electronic device comprising:
a substrate;
a nanowire mesh formed on the substrate and including a plurality of crossing points cross-coupled with a plurality of unit nanowires; and
a first electrode and a second electrode electrically connected to the nanowire mesh.

2. The electronic device of claim 1, wherein the crossing point is formed by cross-coupling the unit nanowire in one of X, Y, and T forms.

3. The electronic device of claim 2, wherein the crossing point is disposed at a predetermined interval.

4. The electronic device of claim 1, wherein a width of the crossing point is greater than a width of the unit nanowire.

5. The electronic device of claim 1, wherein a width of the unit nanowire is 1 μm or less.

6. The electronic device of claim 1, wherein the substrate comprises a flexible substrate.

7. An electronic device comprising:
a substrate;
a nanowire mesh formed on the substrate and including a plurality of openings; and
a first electrode and a second electrode electrically connected to the nanowire mesh.

8. The electronic device of claim 7, wherein the opening has one of a circular shape, an elliptical shape, or a polygonal shape.

9. The electronic device of claim 7, wherein the opening has a polygonal shape, and a side of the opening has a length of 1 μm or less.

10. The electronic device of claim 7, wherein the nanowire mesh has a thickness of 1 μm or less.

11. The electronic device of claim 7, wherein
the opening has a polygonal shape, and a width of the nanowire mesh disposed at a region in which vertexes of the adjacent openings meet each other is greater than a width of a nanowire mesh disposed between sides of adjacent openings.

12. The electronic device of claim 7, wherein the substrate comprises a flexible substrate.

13. An electronic device comprising:
a substrate;
a gate electrode formed on the substrate;
a gate insulation layer formed on the gate electrode;
a nanowire mesh formed on the gate insulation layer, and including a plurality of crossing points cross-coupled with a plurality of unit nanowires, a channel region, a source region, and a drain region; and
a source electrode and a drain electrode electrically connected to the source region and the drain region of the nanowire mesh.

14. The electronic device of claim 13, wherein the gate electrode comprises a first gate electrode having a same plane shape as a shape of the nanowire mesh overlapping with the gate electrode.

15. The electronic device of claim 14, further comprising
a second gate electrode formed on the substrate and including a signal line overlapping with the first gate electrode and transferring a gate signal.

16. The electronic device of claim 13, wherein the gate insulation layer surrounds the nanowire mesh.

17. The electronic device of claim 16, wherein the gate insulation layer comprises a contact opening exposing the source region and the drain region, and
the source electrode and the drain electrode are connected to the source region and the drain region through the contact opening.

18. The electronic device of claim 13, wherein the crossing point is formed by cross-coupling the unit nanowire in one of X, Y, and T forms.

19. An electronic device comprising:
a substrate;
a gate electrode formed on the substrate;
a gate insulation layer formed on the gate electrode;
a nanowire mesh formed on the gate insulation layer, and including a plurality of openings, a channel region, a source region, and a drain region; and
a source electrode and a drain electrode electrically connected to the source region and the drain region of the nanowire mesh.

20. The electronic device of claim 19, wherein the gate electrode comprises a first gate electrode having a same plane shape as a shape of the nanowire mesh overlapping with the gate electrode.

21. The electronic device of claim 20, further comprising
a second gate electrode formed on the substrate and including a second gate electrode overlapping with the unit nanowire between the opening and the adjacent opening and transferring a gate signal,
wherein the second gate electrode makes contact with the first gate electrode.

22. The electronic device of claim 19, wherein the gate insulation layer surrounds the nanowire mesh.

23. The electronic device of claim 19, wherein the gate insulation layer comprises a contact opening exposing the source region and the drain region, and
the source electrode and the drain electrode are connected to the source region and the drain region through the contact opening.

24. The electronic device of claim 19, wherein the nanowire mesh has a thickness of 1 μm or less.

25. The electronic device of claim 24, wherein the opening has a polygonal shape, and a width of the nanowire mesh disposed at a region in which vertexes of the adjacent openings meet each other is greater than a width of a nanowire mesh disposed between sides of the adjacent openings.
